(19) United States
(12) Patent Application Publication
(10) Pub. No.: US 2018/0301774 A1
(43) Pub. Date: Oct. 18, 2018

(54) HEAT EXCHANGER DEVICE FOR CONFINED SPACES

(71) Applicant: Gerard R. Campeau, Newmarket (CA)

(72) Inventor: Gerard R. Campeau, Newmarket (CA)

(21) Appl. No.: 15/732,973

(22) PCT Filed: Jul. 25, 2016
(86) PCT No.: PCT/CA2016/000197

§ 371 Date: Jan. 22, 2018

(51) Int. Cl. H01M 10/6557; F28F 3/12; H01M 10/617; H01M 10/625; H01L 35/30

(52) U.S. Cl. CPC H01M 10/6557; F28F 3/12; H01M 10/617; B60K 2001/0438; H01L 35/30; F28F 2255/02; H01M 2220/20; H01M 10/625

(57) ABSTRACT

This application is directed to a compact heat transfer system for use in heat transfer applications occurring in confined spaces. There is a need to improve heat transfer efficiencies in heat transfer systems designed for confined spaces. The heat exchanger device (14) of the present application, comprises a bladder (16) configured to contain a heat transfer fluid, and a recirculating fluid path (20) formed by a conduit circuit (36) to operatively communicate with the bladder, the bladder configured to provide shape-conformable interfaces (24, 82, 84) for heat transfer between the heat transfer fluid and an exposed surface (26) within the confined space (12). The conduit circuit (36) further extends through a secondary heat exchange unit (38) located at a heat generating device (30).

### FIELD OF THE DISCLOSURE

The present disclosure relates to heat transfer for devices operating in confined spaces, and/or to heat transfer for devices mounted at support locations.

### BACKGROUND

Seebeck Effect generators are commonly used for powering batteries to power an uplink transmitter to remotely control systems in confined spaces, such as underground manhole rooms. It is well known that, when temperature conditions are high (90° F. or higher) and Humidity conditions are above 80% in such confined spaces, it is difficult to efficiently remove or transfer heat from the cold side of the Seebeck Effect generator. This challenge is not limited to Seebeck Effect generators, but applies to other heat transfer applications where cooling is required in a confined space.

Attempts to cool confined spaces have generally involved gaining access outside the confined space for a coolant source. Otherwise, the rated capability of the heat generating device is constrained to the limits of heat generated by it, to accommodate the heat transfer conditions within the confined space.

It would be desirable to provide improved efficiencies for heat transfer in confined spaces, and also to improve cooling or heating of devices in mounted configurations.

### SUMMARY

Some aspects of this disclosure may provide a method and apparatus for that overcome some of the drawbacks of known techniques, or at least, provides the public with a useful alternative.

In an aspect, there is provided a heat exchanger device for a confined space, comprising a bladder configured to contain a heat transfer fluid, and a recirculating fluid path to operatively communicate with the bladder, the bladder configured to provide a shape-conformable first interface for heat transfer between the heat transfer fluid and an exposed surface within the confined space.

In another aspect, there is provided a utility system configured for operating inside a confined space, comprising a first heat exchanger configured to be operably associated with a utility module operating in the confined space for transferring heat therewith, a second heat exchanger including a bladder configured to contain a heat transfer fluid, and a recirculating fluid path to operatively communicate with the bladder, the bladder configured to provide a shape-conformable first interface for heat transfer between the heat transfer fluid and an exposed surface within the confined space, and a recirculating module operatively communicating with the recirculating fluid path, for directing the recirculating fluid between the first and second exchangers to cool and/or to heat the utility module.

In another aspect, there is provided a confined space utility installation, comprising the utility system of one or more aspects herein, the second heat exchanger positioned on a ground surface, so that the bladder is in shape-conforming contact therewith, and a protective cover module for protectively covering the bladder.

In another aspect, there is provided a method of cooling a utility module in a confined space, comprising providing the utility system as defined in one or more aspects herein, locating the bladder of the second heat exchanger in shape-conforming contact with a ground surface in the confined space, and activating the recirculating module.

In another aspect, there is provided a utility assembly, comprising a utility module configured to require cooling during operation thereof, the utility module including a designated heat transfer zone for heat transfer therethrough, and a heat exchange module configured to be positioned between the utility module and an external support surface, the heat exchange module including a bladder configured to contain a heat transfer fluid, with a first surface region for shape-conforming contact with a surface region of the utility module in the designated heat transfer zone to form a first heat transfer interface therewith and a second surface region for shape-conforming contact with the external support surface to form a second heat transfer interface therewith, thereby to establish a heat transfer path from the utility module to the external support surface via the first interface, the heat transfer fluid, and the second interface.

In another aspect, there is provided a battery assembly comprising at least one power generating module and at least one heat exchange bladder, the bladder containing heat transfer fluid and configured to provide at least one shape-conforming first heat transfer interface with the power generating module and at least one second shape-conforming heat transfer interface for heat transfer with an external surface, wherein the bladder is configured to be intimately contiguous therewith.

In another aspect, there is provided a method of cooling a vehicle comprising a chassis, a motor, and a battery to power the motor, the battery being mounted on the chassis at a designated heat transfer location defined by at least one designated heat transfer surface thereon, and a heat exchange bladder positioned between the battery and the chassis with intimately contiguous contact with the both the battery and the at least one of the designed heat transfer surface, to form a first heat transfer interface between the battery and the bladder, and a second heat transfer interface between the bladder and the chassis.

### BRIEF DESCRIPTION OF THE FIGURES

Several embodiments of the present disclosure will be provided, by way of examples only, with reference to the appended drawings, wherein:

FIGS. 1 to 4 are perspective, end, plan and side views, respectively of a utility installation in a confined space;

FIGS. 5 and 6 are schematic cross sectional views of utility assemblies;

FIG. 7 is a schematic side view of a vehicle;

FIG. 8 is a schematic sectional view of a portion of the assembly of FIG. 5; and

FIG. 9 is a schematic side view of a battery assembly.

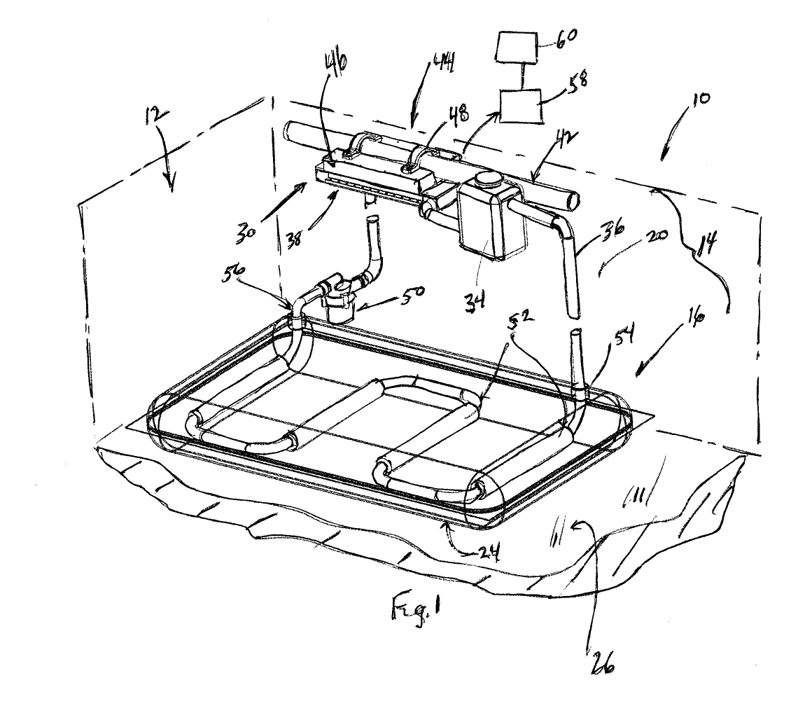

### DETAILED DESCRIPTION

It should be understood that the invention is not limited in its application to the details of construction and the arrangement of components set forth in the following description or illustrated in the drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical, mechanical or electrical connections or couplings. Furthermore, and as described in subsequent paragraphs, the specific mechanical and/or other configurations illustrated in the drawings are intended to exemplify embodiments of the invention. However, other alternative mechanical and/or electrical or other configurations are possible which are considered to be within the teachings of the instant disclosure.

The term “confined space” means an enclosed area with limited space and/or accessibility, which may be occasionally entered by workers for maintenance. An example is the interior of a manhole room, or utility room beneath a street surface, providing access to utility services. Other confined spaces may include spaces found in subways, tunnels, mines or subterranean access locations, as well as ships and submarines. Confined spaces may also be found above ground in locations such as elevator shafts, ventilation systems and the like, where the design constraints of the confined space limit the ability to ventilate or provide cooling, as well as crawl spaces under domestic houses, walkways, or subfloors on buildings and sheds, or in vehicles, such as cars and trucks, planes, trains and the like.

The terms “shape-conforming” and “shape-conformable” means the act or ability to adjust or reconfigure shape, for instance of a bladder membrane surface under weight of fluids in the bladder, to an irregular shape of an external surface on which or against which the bladder is pressed, either by the force of gravity or by some other source of pressure, such as a ground surface, thereby to accommodate regular, irregular or random discontinuities therein.

The term “intimately contiguous” describes a physical interaction between two surfaces, in which at least one of the surfaces is shape-conforming or shape conformable, to minimize air space forming discontinuities along a boundary of contact between them.

Some exemplary embodiments may enable relatively larger power outputs to be generated by thermoelectric power modules in confined spaces, in comparison with conventional configurations, by a novel pump bladder configuration, along with an oversized hot side plate to maximize heat absorption into the hot side of such thermoelectric power modules.

Some exemplary embodiments are represented in the figures, which illustrate a heat exchanger installation 10 for a confined space 12. The installation includes a heat exchanger generally shown at 14 having a bladder 16 which is configured to contain a heat transfer fluid. Also provided is a recirculating fluid path generally shown at 20, which is operably associated with the bladder 16 for heat transfer between recirculating fluid present in the path 20 and the heat transfer fluid in the bladder 16. The bladder 16 is also configured to provide a first interface 24 for heat transfer between the heat transfer fluid therein and a conductive exposed surface 26 within the confined space 12.

The heat exchanger 14 may thus be configured to enable cooling of the recirculating fluid, thereby to cool the confined space 12 or an object therein, such as a Seebeck Effect generator shown generally at 30. Alternatively, the heat exchanger 14 may be configured to enable heating of the recirculating fluid, thereby to heat the confined space or an object therein.

The bladder 16 has a side wall membrane 32 which is configured to form intimately contiguous contact over substantially an entire designated surface area thereof, with the conductive surface 26 in the confined space 12. Among other possible examples, the side wall membrane 32 may include a metallic layer or foil, and include one or more of more of Mylar™, ultrathin silicon, and aluminum foil. The side wall membrane 32 may be formed with one or more layers, which may be sandwiched into a one piece cross-section or a multiple piece cross-section. In the latter case, the layers may be separated with an intermediate heat transfer fluid or configured in another way, in order to develop, produce or maintain an efficient, or at least commercially effective, heat transfer coefficient function across the interface formed by the side wall membrane, without departing from the scope of the present disclosure.

The bladder 16 is thus configured to be shape-formable and thus to shape-conform to the heat-conductive exposed surface 26, such as a wall surface, floor surface, pipe surface of the like, made from soil, concrete, steel or the like, thereby making intimately contiguous thermal contact therewith, and in so doing transferring heat there between, so that the bladder enables the exposed surface 26, to serve as a heat sink (or heat dissipater).

In some exemplary embodiments, a radiator (not shown) with a small low power fan, may be located in line with the recirculating path 20 and sitting adjacent an exposed surface 26, to add additional cooling if required. Further, the bladder 16 may be scaled by providing multiple modular bladders added in series (or parallel) in the fluid path 20 to offer additional cooling as needed based on calculated heat dissipation requirements, without departing from the scope of the present disclosure.

In some embodiments, the bladder 16 may also serve as a pressure vessel for thermal expansion with increasing temperature of the heat transfer fluid. In one configuration, this may occur where the heat transfer fluid passes through, is contained, or is resident, the bladder 16 and the recirculating path extends through the bladder 16, and thus the heat transfer fluid, wherein the recirculating fluid path 20 carries a separate and distinct recirculating fluid. Alternatively, a pressure expansion chamber may be provided separately, as shown at 34. In any case, heat may be transferred between the heat transfer fluid in the bladder 16 and an exposed surface 26 in the confined space.

In some embodiments, the bladder 16 may be made of a thin material Mylar™ foil, such as from about 2 mil to about 10 mil, or otherwise with an effective thickness, in combination with other factors affecting heat coefficients and the like, to conduct directly into the concrete floor, as a result of the shape conforming and heat transfer characteristics of the foil. Examples of commercially available foil material include Dupont™ H-37232-3, or Sorbent Systems™, PAKVF4, PAKVF2.5M, or PAKVF4PCAluminum foil layer. Polyester films or other films offering reinforcing strength, may also be added to reduce possibility of puncture, without departing from the scope of the present disclosure.

In one configuration, the bladder 16 is thus configured to shape-conform to an exposed surface in the confined space, including a ground, floor, wall or ceiling surface in the confined space. This may involve the bladder wrapping around, at least in part, an exposed surface of a piping or other configuration in the confined space.

The recirculating fluid path 20 is formed by a conduit circuit 36 extending through the bladder 16 as well as through a secondary heat exchange unit 38 at a heat-generating device, such as the Seebeck Effect generator 30, which is in operative relation with an external casing surface 42 of a pipeline segment 44 extending through the confined space 12. In this case, a heat conductive block 46 is coupled to the external casing surface 42 by way of clamps shown at 48, and provides a third interface to transfer heat between the block and the heat generating module, such as the hot side of the Seebeck Effect generator 30, while the secondary heat exchange unit 38 is in contact with the cool side thereof. While a single Seebeck Effect generator 30 is shown, multiples thereof may be deployed, without departing from the scope of the present disclosure.

The heat conductive block 46 may be formed from a range of materials such as copper or aluminum, though other highly conductive metals may also be used, such as graphene, graphite, new diamond materials, or titanium in order that block 46 may provide the third interface with effective thermal heat flux transfer rates.

The one or more thermoelectric Seebeck Effect generators 30 may then be attached to the conductive block 46. In this case, the conduit circuit 36 may be installed adjacent to the hot side of the block 46 to draw heat therefrom. During operation, heat may then move from the “cold” side of the block 46 to the “hot” side, and then into the recirculation fluid residing in the conduit circuit 36. The cold side may thus be configured to absorb heat at an effective rate and transfer the thermal energy via conduction through the third interface between the block and the recirculating fluid (for example water, water/glycol, water/alcohol), which is then delivered to the bladder 16 which is placed against, and thus closely conforming to, a suitable exposed surface thereby conducting heat in the liquid directly into the contacting dissipating surface.

Located in the conduit circuit 36 between the bladder 16 and the secondary heat exchange unit 38 is a low volume pump unit 50. A relatively small capacity pump, such as those commercially available from TOPSFLO or TCS MICROPUMPS with rated flow rates ranging from about 300 ml to about 4000 m1 may be used to minimize, if not eliminate measurable head pressure, to minimize operating power requirements. Pump size would therefore be dependent on system specification.

The conduit circuit 36 extends through the bladder 12 and, in this example, follows a serpentine configuration, with finned conduit segments provided at regular intervals, for instance in the elongate linear sections thereof, as illustrated schematically at 52. In this case, the bladder 16 and conduit circuit 36 are configured to cooperate to form an entry transition and an exit transition, by way of transition couplings shown at 54, 56.

In the configuration shown, the Seebeck Effect generator unit 30 is configured to generate sufficient power to continually charge a battery 58 for a data transmitter 60 to convey data concerning the condition of fluids in the pipeline segment 44, and may include or more of such as flow rate, temperature and/or operating pressure. However, other confined space utility installations may also be cooled with the system disclosed herein, such as installations of pumps, transformers, switching, computer systems, graphics terminals, among others, without departing from the scope of the present disclosure.

Thus, in some exemplary embodiments, the conduit circuit may be in the form of a recirculating loop, either a closed or an open loop, which may then be coupled with the bladder to reduce operating power requirements. One example includes a low flow liquid sink using parallel flow and jet cooling with a whale fin configuration that creates turbulent flow even at very low flow rates (such as below 1 to 2 liters per minute) by creating micro vortices that speed the liquid up as it passes by the peaks and thru the valleys to minimize cavitation effects, if any.

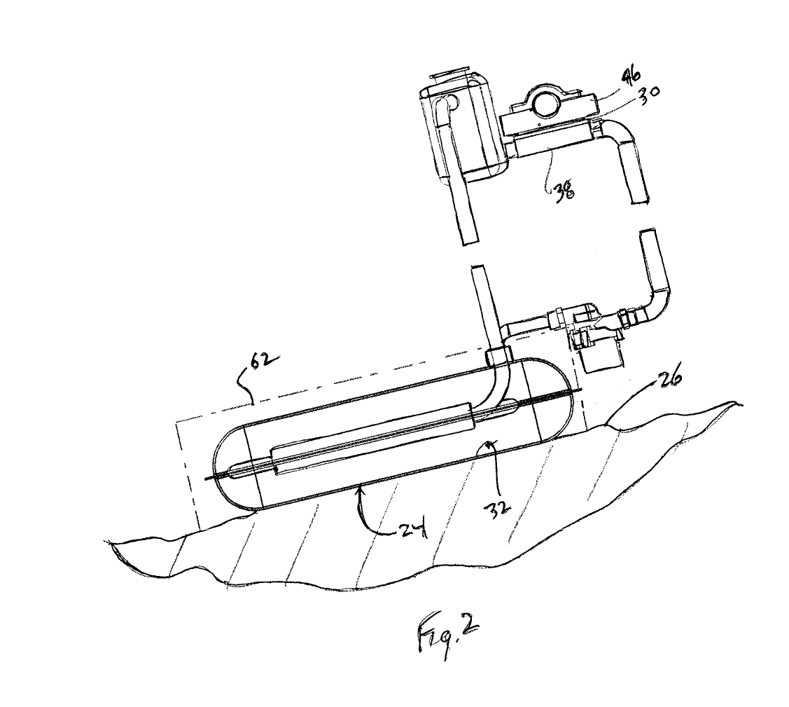

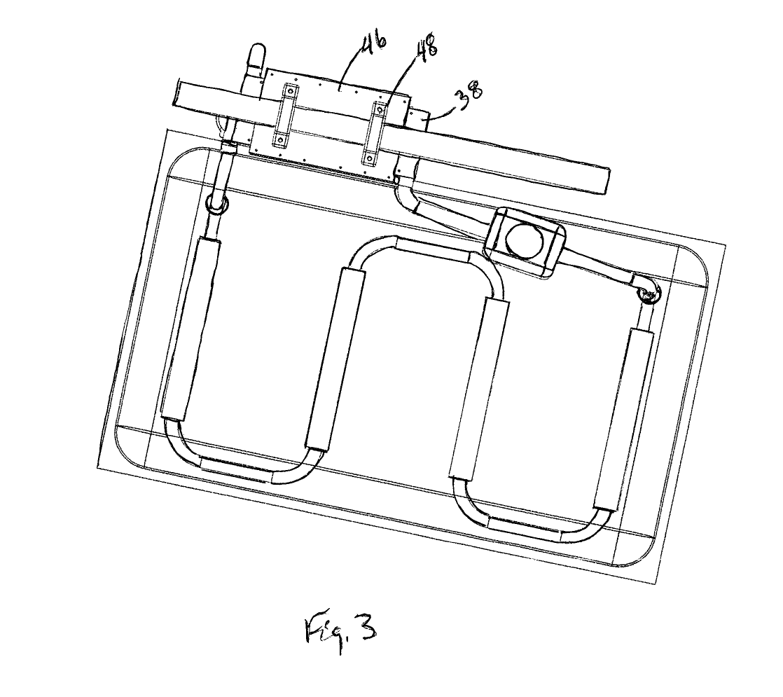

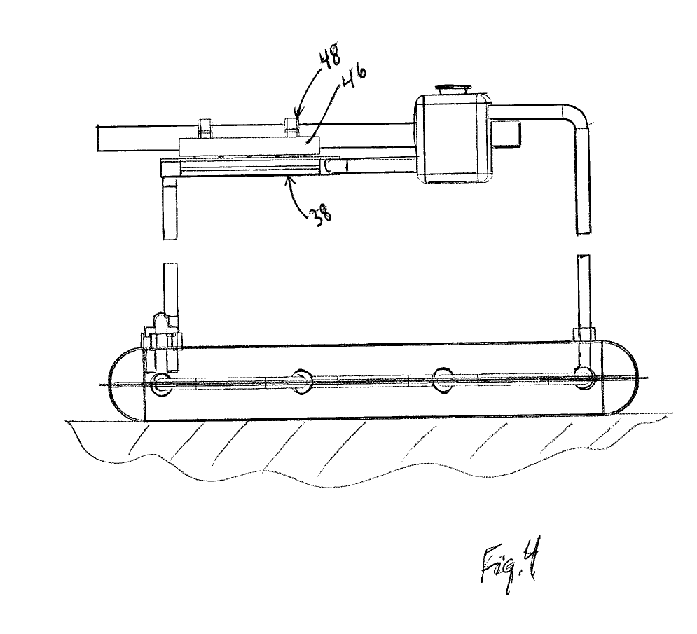

It will be understood that the dimensions presented in the figures are for illustration only, particularly in respect of the thickness, length and width of the bladder 16. A number of factors may play roles in configuring a heat exchange system for a particular confined space. The heat transfer coefficient of the bladder, particularly at the first interface with the exposed surface will contribute to governing heat transfer rates. With increasing thickness of the bladder with fluid, effective pressures at the first interface will also increase which, in some cases, will enhance the contiguous, or intimate, contact between the exposed surface and the effective surface of the bladder. In other words, with increasing effectiveness of contiguity or intimacy, the larger the collective contact surface area of the bladder that is in direct physical contact with the exposed surface. The bladder 16 may be protected by a cover, as shown at 62 in FIG. 2, to protect the bladder 16 from contact with objects potentially causing damage and/or puncturing. If desired, the bladder may be integrally formed with the cover provided that an effective first interface may be established between the contact area of the bladder and the exposed surface. The section of the conduit path passing through the bladder or otherwise providing the second interface may be formed integrally with the bladder, that is by baffles extending between the opposed sides of the bladder, or alternatively formed between adjacent layers forming the bladder, and defined by ultrasonic or other forming techniques. While the installation 10 deploys a first recirculating fluid in the conduit circuit 36, and a second heat transfer fluid in the bladder 16, it will be understood that other configurations may deploy a single fluid in the conduit circuit, which is then emptied into the bladder for heat transfer functions, and then drawn from the bladder for recirculation, without departing from the scope of present the disclosure.

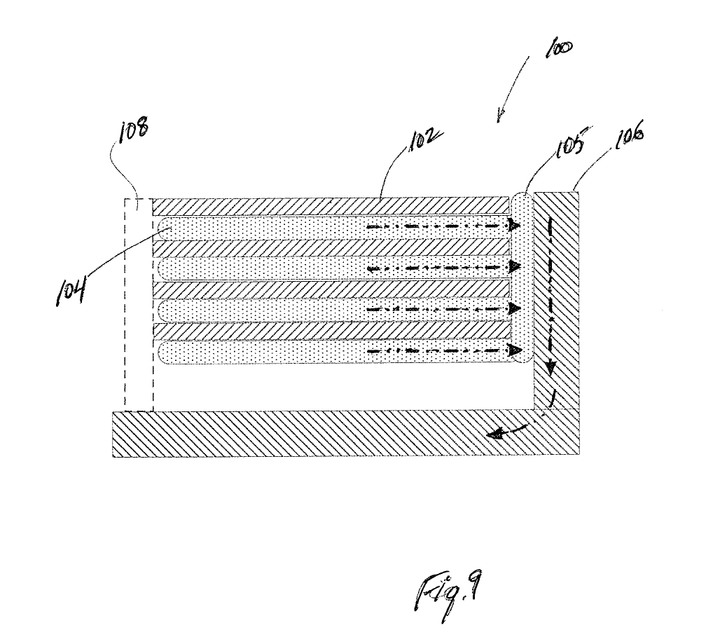

Another exemplary embodiment is shown in FIG. 5, which illustrates a utility assembly 70, comprising a utility module 72 configured to require cooling during operation thereof. The utility module 72 includes a designated heat transfer zone 74 for heat transfer therethrough, and a heat exchange module 76 configured to be positioned between the utility module 72 and an external support surface 78. The heat exchange module includes a bladder 80 configured to contain a heat transfer fluid, with a first surface region for shape-conforming contact with a surface region of the utility module in the designated heat transfer zone to form a first heat transfer interface 82 therewith and a second surface region for shape-conforming contact with the external support surface to form a second heat transfer interface 84 therewith. FIG. 8 illustrates a magnified and exaggerated representation of the shape-conforming contact of the second surface region 80a on the lower surface of the bladder and the external support surface 78, showing irregularities therein and the bladder accommodating them, with minimal air filled discontinuities in the boundary between them.

Thus, the assembly is configured to establish a heat transfer path from the utility module 72 to the external support surface 78 via the first interface 82, the heat transfer fluid, and the second interface 84.

In this example, the utility module 72 is a battery 86 though other utility modules are contemplated for other heat generating modules, such as a circuit board.

The heat exchange module includes a housing 88, and the designated heat transfer surface zone includes an inner region 90 contained by the housing 88, with the second interface 84 being presented in a region exterior to the housing. Thus, in this configuration, the bladder 80 has a portion thereof which is exposed to an opening 94 which is aligned with the exterior support surface 78.

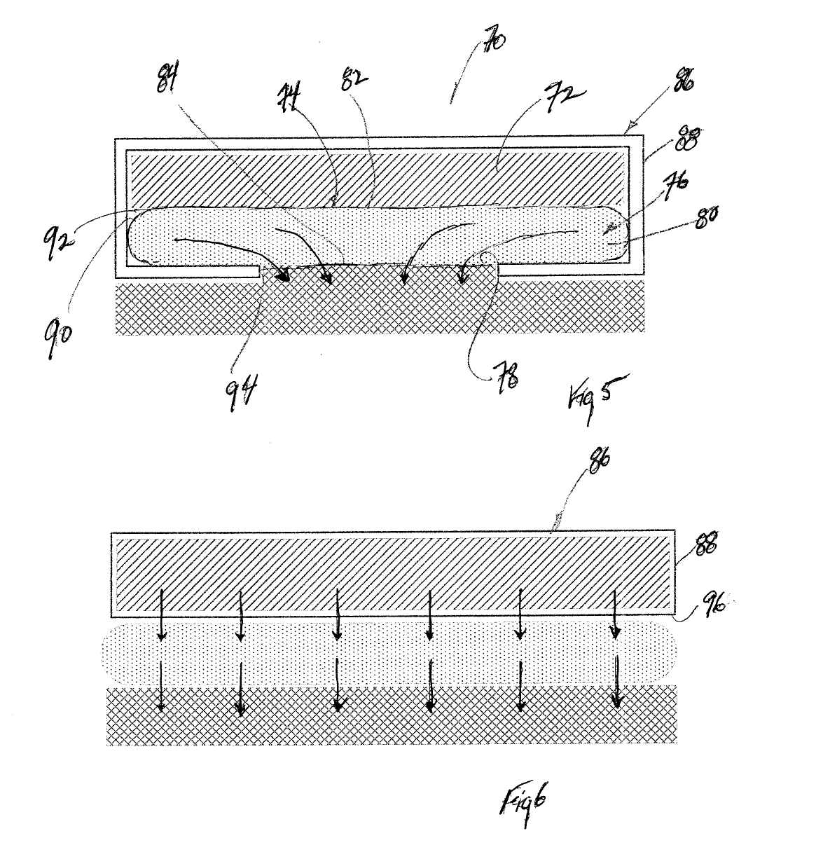

FIG. 6 shows another configuration of a utility assembly, in which the battery 86 includes a housing 88, and the designated heat transfer zone includes a designated outer surface 96 on the housing.

In another exemplary embodiment, as shown in FIG. 9, there is provided a battery assembly 100 comprising at least one power generating module 102, in this case a plurality of power generating modules in a stack, and a plurality of heat exchange bladders 104, all but one of which provide a pair of shape-conforming first heat transfer is interfaces, each of which is adjacent, and in intimately contiguous contact with, a corresponding one of said modules 102.

Each bladder 104 contains heat transfer fluid and configured to provide at least one shape-conforming first heat transfer interface with the power generating module and at least one second shape-conforming heat transfer interface for heat transfer with an external surface, wherein the bladder is configured to be intimately contiguous therewith. Thus, all but one of the bladders 104 are each interspersed between a corresponding pair of the modules 102 in the stack. An additional bladder 105 is provided at which is placed in contact with the ends of each of the interspersed bladders 104, so that the interspersed bladders 104 are in heat transfer relationship, either directly or indirectly, with an external surface on external support 106, provided in part by a mounting assembly shown schematically at 108. Thus, heat generated in each of the modules 102 is directed through the neighboring interspersed bladders 104, which is then transferred by to the external support via additional bladder 105.

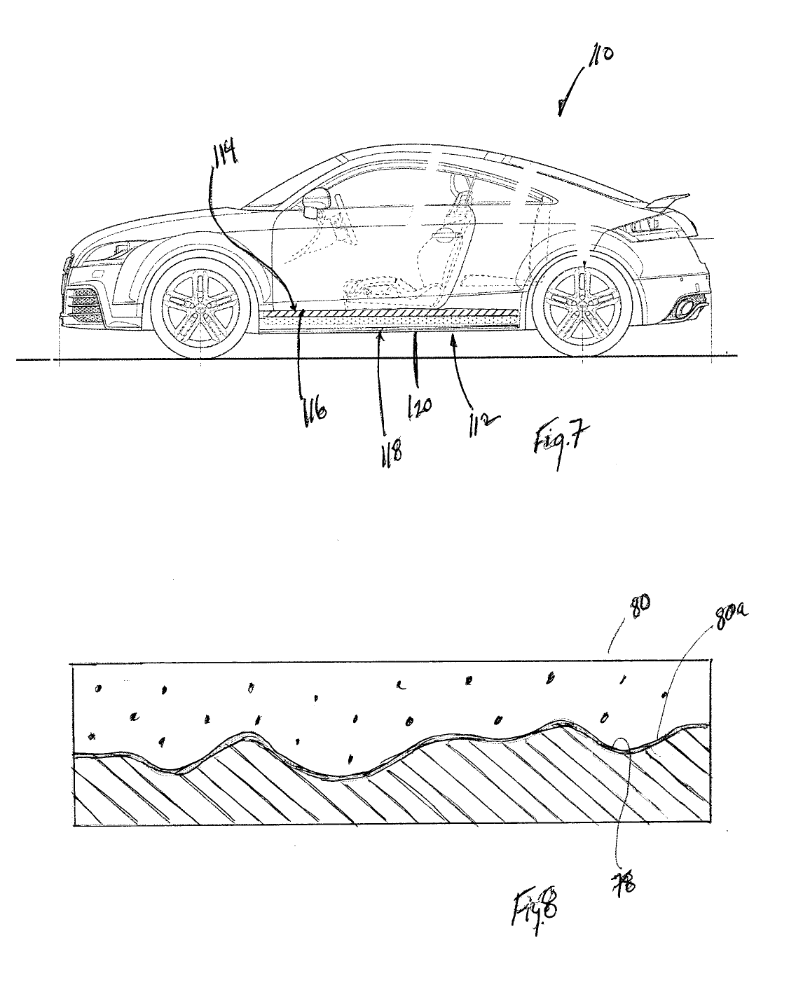

Referring to FIG. 7, there is provided a vehicle 110 comprising a chassis 112, a motor (not shown), and a battery 114 to power the motor. The battery 114 is mounted on the chassis 112 at a designated heat transfer location 118 defined by at least one designated heat transfer surface 120 thereon, and a heat exchange bladder 116 positioned between the battery 114 and the chassis 112 with intimately contiguous contact with the both the battery 114 and the at least one of the designed heat transfer surface 120, to form a first heat transfer interface between the battery 114 and the bladder 116, and a second heat transfer interface between the bladder 116 and the chassis 112.

While the present disclosure describes various exemplary embodiments, the disclosure is not so limited. To the contrary, the disclosure is intended to cover various modifications and equivalent arrangements, as will be readily appreciated by the person of ordinary skill in the art.

1. A heat exchanger device for a confined space, comprising a bladder configured to contain a heat transfer fluid, and a recirculating fluid path to operatively communicate s with the bladder, the bladder configured to provide a shape-conformable first interface for heat transfer between the heat transfer fluid and an exposed surface within the confined space.

2. A device as defined in claim 1, wherein the recirculating fluid path is configured to receive recirculating fluid therein, the path being operably associated with the bladder for heat transfer between the recirculating fluid and the heat transfer fluid, the recirculating fluid path including a fluid boundary providing a second interface between the recirculating fluid and the heat transfer fluid.

3. A heat exchanger as defined in claim 2, the heat exchanger configured to enable cooling of the recirculating fluid, thereby to cool the confined space or an object therein.

4. A heat exchanger as defined in claim 2, the heat exchanger configured to enable heating of the recirculating fluid, thereby to heat the confined space or an object therein.

5. A heat exchanger as defined in claim 2, the bladder further comprising a side wall membrane at the shape-conformable first interface.

6. A heat exchanger as defined in claim 5, the side wall membrane including a metallic layer.

7. A heat exchanger as defined in claim 5, the side wall membrane including one or more of Mylar™, ultrathin silicon, aluminum foil and/or combinations or subcombinations thereof.

8. A heat exchanger as defined in claim 2, the bladder and the recirculating fluid path cooperating to form a recirculating fluid path entry transition and a recirculating fluid path exit transition, with the recirculating fluid path extending through an interior of the bladder containing the heat transfer fluid to form the second interface.

9. A heat exchanger as defined in claim 8, the recirculating path extending in a serpentine configuration through the interior of the bladder.

10. A heat exchanger as defined in claim 9, further comprising a plurality of fins distributed along the fluid boundary.

11. A heat exchanger as defined in claim 1, wherein the bladder is configured to wrap around, at least in part, an exposed surface of a piping configuration in the confined space.

12. A utility system configured for operating inside a confined space, comprising a first heat exchanger configured to be operably associated with a utility module operating in the confined space for transferring heat therewith, a second heat exchanger including a bladder configured to contain a heat transfer fluid, and a recirculating fluid path to operatively communicate with the bladder, the bladder configured to provide a shape-conformable first interface for heat transfer between the heat transfer fluid and an exposed surface within the confined space, and a recirculating module operatively communicating with the recirculating fluid path, for directing the recirculating fluid between the first and second exchangers to cool and/or to heat the utility module.

13. A system as defined in claim 12, the recirculating module further comprising at least one pump for pumping the recirculating fluid.

14. A system as defined in claim 12, further comprising the utility module including a thermoelectric device, and a heat absorbing block configured to be anchored on a supply pipeline travelling through and exposed within the confined space, the thermoelectric device configured to be operably mounted adjacent the heat absorbing block to form a second heat transfer interface therewith.

15. A confined space utility installation, comprising the utility system of claim 12, the second heat exchanger positioned on a ground surface, so that the bladder is in shape-conforming contact therewith, and a protective cover module for protectively covering the bladder.

16. A method of cooling a utility module in a confined space, comprising providing the utility system as defined in claim 12, locating the bladder of the second heat exchanger in shape-conforming contact with a ground surface in the confined space, and activating the recirculating module.

17. A method as defined in claim 16, wherein the utility module is a thermoelectric device.

18. A utility assembly, comprising a utility module configured to require cooling during operation thereof, the utility module including a designated heat transfer zone for heat transfer therethrough, and a heat exchange module configured to be positioned between the utility module and an external support surface, the heat exchange module including a bladder configured to contain a heat transfer fluid, with a first surface region for shape-conforming contact with a surface region of the utility module in the designated heat transfer zone to form a first heat transfer interface therewith and a second surface region for shape-conforming contact with the external support surface to form a second heat transfer interface therewith, thereby to establish a heat transfer path from the utility module to the external support surface via the first interface, the heat transfer fluid, and the second interface.

19. An assembly as defined in claim 18, wherein the utility module is a battery

20. An assembly as defined in claim 19, wherein the battery includes a housing, the designated heat transfer zone including a designated outer surface on the housing.

21. An assembly as defined in claim 18, wherein the heat exchange module includes a housing, and the designated heat transfer surface zone includes an inner region contained by the housing, with the second interface being presented in a region exterior to the housing.

22. A battery assembly comprising at least one power generating module and at least one heat exchange bladder, the bladder containing heat transfer fluid and configured to provide at least one shape-conforming first heat transfer interface with the power generating module and at least one second shape-conforming heat transfer interface for heat transfer with an external surface, wherein the bladder is configured to be intimately contiguous therewith.

23. An assembly as defined in claim 22, wherein the external surface is a designated surface location at a ground location, a vehicle chassis location, or a building location.

24. An assembly as defined in claim 22, further comprising a mounting structure for mounting the device adjacent the external surface.

25. An assembly as defined in claim 22, wherein the at least one power generating module further comprises a plurality of power generating modules in a stack, the at least one shape-conforming first heat transfer interface including a pair of shape-conforming first heat transfer interfaces, each shape-conforming first heat transfer interface being adjacent, and in intimately contiguous contact with, a corresponding one of said modules.

26. An assembly as defined in claim 25, wherein the at least one heat exchange bladder further comprises a plurality of heat exchange bladders, wherein each of the bladders is interspersed between a corresponding pair of said modules in the stack.

27. An assembly as defined in claim 26, wherein the plurality of heat exchange bladders are in heat transfer relationship, either directly or indirectly, with the external surface.

28. A vehicle comprising a chassis, a motor, and a battery to power the motor, the battery being mounted on the chassis at a designated heat transfer location defined by at least one designated heat transfer surface thereon, and a heat exchange bladder positioned between the battery and the chassis with intimately contiguous contact with the both the battery and the at least one of the designed heat transfer surface, to form a first heat transfer interface between the battery and the bladder, and a second heat transfer interface between the bladder and the chassis.
